(19) United States
(12) Patent Application Publication
(10) Pub. No.: US 2021/0265110 A1
(43) Pub. Date: Aug. 26, 2021

(54) CURRENT TRANSFORMER

(71) Applicant: Fluke Corporation, Everett, WA (US)

(72) Inventors: Shounan Luo, Shanghai (CN); Fang Li, Shanghai (CN)

(21) Appl. No.: 17/257,482

(22) PCT Filed: Jun. 28, 2019
(86) PCT No.: PCT/CN2019/093544

§ 371 Date: Dec. 31, 2020

(30) Foreign Application Priority Data
Jul. 2, 2018 (CN) 201810707751.5

(51) Int. Cl. H01F 38/30; H01F 27/28; H01F 27/24; H01F 27/36

(52) U.S. Cl. CPC H01F 38/30; H01F 27/363; H01F 27/24; H01F 27/28

(57) ABSTRACT

A current transformer includes first and second transformer assemblies that each respectively comprise first and second groups of stacked iron core components. A first interface and a second interface are defined at an end of the first transformer assembly. A third interface and a fourth interface are defined at an end of the second transformer assembly. At least one of the first interface and the second interface is detachably connected with at least one of the third interface and the fourth interface. When the first and second transformer assemblies are connected with each other, the first and second groups of iron core components are combined to form a plurality of closed ring-shaped iron cores, and coils are respectively wound on at least two closed ring-shaped iron cores. An enclosed area defined between the first and second transformer assemblies causes induced current to be generated in at least one coil.

### BACKGROUND

### Technical Field

The present application relates to electronic measurement technology, and in particular relates to a detachable current transformer.

### Description of the Related Art

With the wide application of various power systems in industrial production and daily life, a device capable of accurately and conveniently measuring current is needed to monitor the power systems for a safe and effective operation thereof. A traditional ring current transformer can only be used to measure AC current, and cannot measure DC current. Moreover, when measuring AC current with low frequency, a ring current transformer produces a large error. Therefore, when there are both DC current and AC current, an instrument which can accurately measure AC and DC components of current is needed.

At present, there is a current transformer having a plurality of ring-shaped iron cores, which can simultaneously measure the AC component and DC component of the current in a conducting wire passing therethrough, and has high measurement accuracy. However, when measuring using the multi-core current transformer, at least one end of the conducting wire needs to be disconnected from the circuit in order to make the conducting wire under test pass through an enclosed area of the transformer, which will cause temporary power outage of the system. In many cases, this temporary power outage will lead to great economic losses and even security risks.

Therefore, what is needed is an instrument that can accurately measure current in a cable under test without power outage.

### BRIEF SUMMARY

The present application provides a detachable multi-core current transformer, which can measure current in a cable under test without power outage.

Disclosed in the present application is a current transformer, which includes a first transformer assembly and a second transformer assembly, wherein two ends of the first transformer assembly are provided with a first assembly end and a second assembly end, the first transformer assembly includes a first group of stacked iron core components, the first group of iron core components is provided with a first interface defined at the first assembly end and a second interface defined at the second assembly end; two ends of the second transformer assembly are provided with a third assembly end and a fourth assembly end, the second transformer assembly includes a second group of stacked iron core components, the second group of iron core components is provided with a third interface defined at the third assembly end and a fourth interface defined at the fourth assembly end. At least one of the first interface and the second interface is detachably connected with at least one of the third interface and the fourth interface, so as to detachably connect the first transformer assembly and the second transformer assembly; the first transformer assembly and the second transformer assembly are configured such that when connected with each other, the first group of iron core components and the second group of iron core components are combined to form a plurality of closed ring-shaped iron cores, and at least two closed ring-shaped iron cores of the plurality of closed ring-shaped iron cores are respectively wound with coils; an enclosed area is defined between the first transformer assembly and the second transformer assembly such that when a cable under test passes through the enclosed area, induced current related to current in the cable under test is generated in at least one coil of the coils.

In some embodiments, at least one coil is wound on the outside of the plurality of closed ring-shaped iron cores and is configured to generate induced current related to the current in the cable under test when the cable under test passes through the enclosed area.

In some embodiments, the first group of iron core components includes two iron core components, the second group of iron core components includes two iron core components, and when the first transformer assembly and the second transformer assembly are connected with each other, the two iron core components of the first group of iron core components and the two iron core components of the second group of iron core components are combined to form two closed ring-shaped iron cores, each closed ring-shaped iron core is respectively wound with a coil, and the outside of the two closed ring-shaped iron cores are further wound with two coils.

In some embodiments, the first group of iron core components includes three iron core components, the second group of iron core components includes three iron core components, and when the first transformer assembly and the second transformer assembly are connected with each other, the three iron core components of the first group of iron core components and the three iron core components of the second group of iron core components are combined to form three closed ring-shaped iron cores, each closed ring-shaped iron core is respectively wound with a coil, and the outside of the three closed ring-shaped iron cores is further wound with a coil.

In some embodiments, the first group of iron core components includes four iron core components, the second group of iron core components includes four iron core components, and when the first transformer assembly and the second transformer assembly are connected with each other, the four iron core components of the first group of iron core components and the four iron core components of the second group of iron core components are combined to form four closed ring-shaped iron cores, and each closed ring-shaped iron core is respectively wound with a coil.

In some embodiments, the first transformer assembly further includes a first housing, and the first housing is configured to confine the first group of iron core components therein; the second transformer assembly further includes a second housing, and the second housing is configured to confine the second group of iron core components therein; the first housing and the second housing are configured such that when the first transformer assembly and the second transformer assembly are connected with each other, the first housing and the second housing are combined to form a closed ring-shaped housing, so as to accommodate the plurality of closed ring-shaped iron cores therein, and the at least one coil wound on the outside of the plurality of closed ring-shaped iron cores is wound on the closed ring-shaped housing.

In some embodiments, at least one of the first interface and the second interface and at least one of the third interface and the fourth interface are provided with interdigitated structures, and the interdigitated structures are capable of being connected with each other in an interdigitated manner when the interfaces are connected with each other.

In some embodiments, each of the first interface, the second interface, the third interface and the fourth interface is provided with a guide member to guide the connection of the interface.

In some embodiments, the guide member of each interface includes a plurality of guide elements, each guide element surrounds one end of one iron core component of the first group of iron core components or the second group of iron core components, each guide element is provided with a paired protrusion part and recess part, and when one interface is connected with another interface, a paired protrusion part and recess part thereof are mated with a paired protrusion part and recess part of a guide element of the other interface.

In some embodiments, the current transformer further includes one or more fasteners for fixing the first transformer assembly and the second transformer assembly together when the interfaces are connected with each other.

In some embodiments, the first interface is detachably connected with the third interface, and the second interface is detachably connected with the fourth interface.

In some embodiments, the first transformer assembly and the second transformer assembly are in a semicircular ring shape.

In some embodiments, at least two iron core components of the first group of iron core components and at least two iron core components of the second group of iron core components are wound with coils, and when the first transformer assembly and the second transformer assembly are connected with each other, the coils respectively wound on the at least two closed ring-shaped iron cores of the plurality of closed ring-shaped iron cores are formed by the coils on at least two iron core components of the first group of iron core components connected with the coils on at least two corresponding iron core components of the second group of iron core components.

In some embodiments, the outside of the first group of iron core components is wound with at least one coil, the outside of the second group of iron core components is wound with at least one coil, and when the first transformer assembly and the second transformer assembly are connected with each other, at least one coil wound on the outside of the plurality of closed ring-shaped iron cores is formed by the at least one coil wound on the outside of the first group of iron core components connected with the at least one corresponding coil wound on the outside of the second group of iron core components.

In some embodiments, the coil wound on each iron core component of the first group of iron core components substantially extends over the entire length from the first assembly end to the second assembly end.

In some embodiments, the coil wound on each iron core component of the second group of iron core components substantially extends over the entire length from the third assembly end to the fourth assembly end.

In some embodiments, at least one iron core component of the first group of iron core components and the second group of iron core components is made of an iron-nickel alloy material.

In some embodiments, the outside of the iron core components and the coils of the first transformer assembly and the second transformer assembly is provided with a metal shielding layer for shielding an external electric field.

In some embodiments, the first transformer assembly further includes a first housing, the first housing is configured to confine the first group of iron core components therein, and the first housing is accommodated in the metal shielding layer; and the second transformer assembly further includes a second housing, the second housing is configured to confine the second group of iron core components therein, and the second housing is accommodated in the metal shielding layer.

The foregoing is a summary of the present application where simplification, generalization, and omitted details may exist. Therefore, it should be appreciated by those skilled in the art that this section is for exemplary illustration only, and not intended to limit the scope of the present application by any means. This summary section is not intended to identify key features or essential features of the claimed subject matter, and is not intended to be used as a supplementary means to identify the scope of the claimed subject matter.

### BRIEF DESCRIPTION OF THE SEVERAL VIEWS OF THE DRAWINGS

The aforementioned and other features of the present application will be more fully and clearly understood through the specification below and the appended claims with reference to the accompanying drawings. It can be understood that these accompanying drawings illustrate only a few embodiments of the present application, and therefore should not be considered as limiting the scope of the present application. By using the drawings, the content of the present application will be more clearly described in detail.

FIG. 1 illustrates an overall structural schematic view of a detachable multi-core current transformer according to one embodiment of the present application.

FIG. 2 illustrates a structural schematic view of a transformer assembly in the current transformer illustrated in FIG. 1.

FIG. 3 illustrates an exploded schematic view of components of a transformer assembly in the current transformer illustrated in FIG. 1.

FIG. 4 illustrates an interface schematic view of a transformer assembly in the current transformer illustrated in FIG. 1.

FIG. 5 illustrates a structural schematic view after mounting of three closed ring-shaped iron cores in the current transformer illustrated in FIG. 1.

FIG. 6 illustrates a schematic diagram of a circuit for sensing primary current in a cable under test according to another embodiment of the present application.

### DETAILED DESCRIPTION

The following detailed description is made with reference to the accompanying drawings constituting a part of the description. Unless otherwise specified in the context, similar reference numerals usually represent similar components in the accompanying drawings. The illustrative embodiments described in the detailed description, the accompanying drawings, and the claims are not limiting. Without departing from the spirit or scope of the subject matter of the present application, other embodiments can be adopted and other modifications can be made. It can be understood that the various aspects of the present application generally described in the present application and graphically presented in the accompanying drawings may be arranged, replaced, combined, and designed in many different configurations, and these different configurations explicitly constitute a part of the present application.

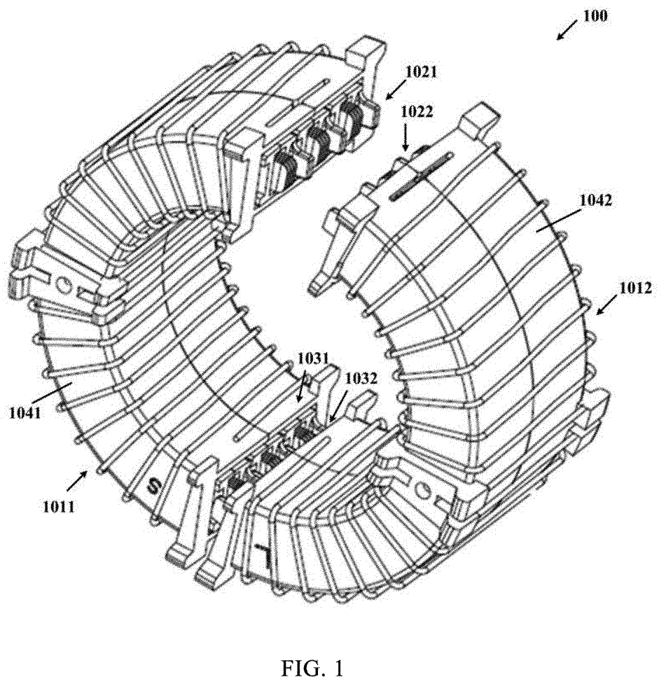

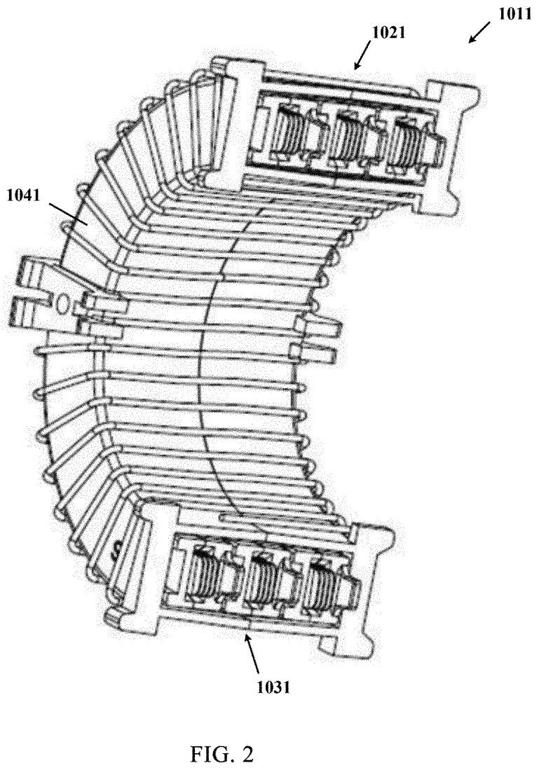

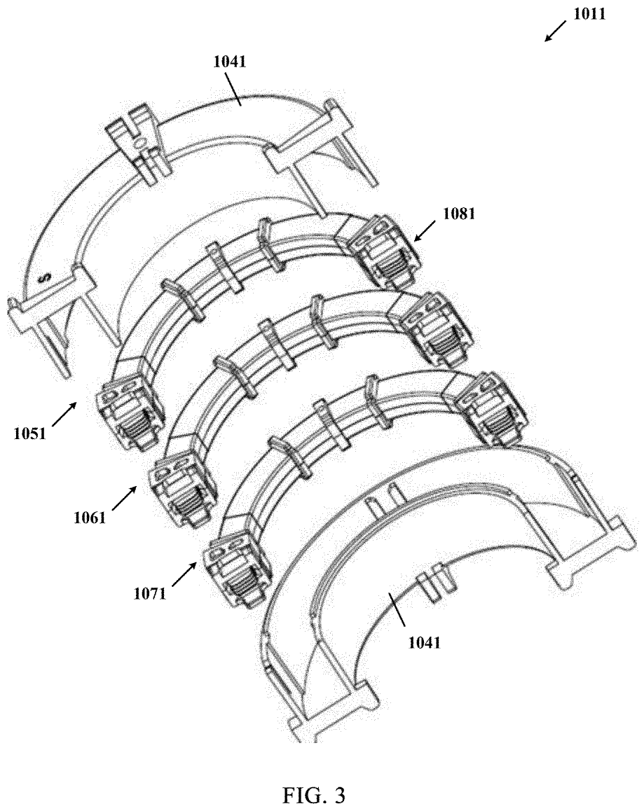

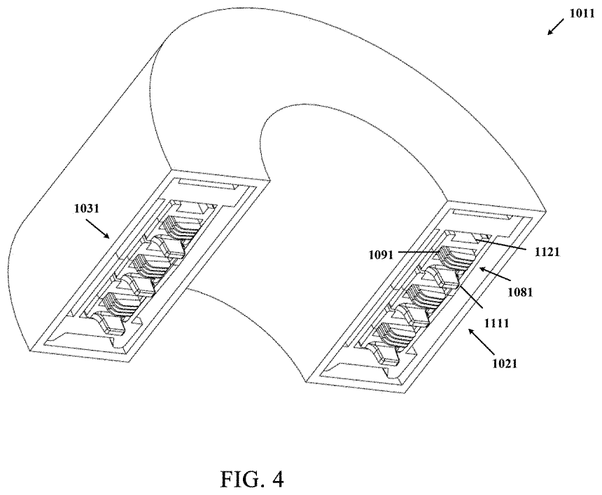

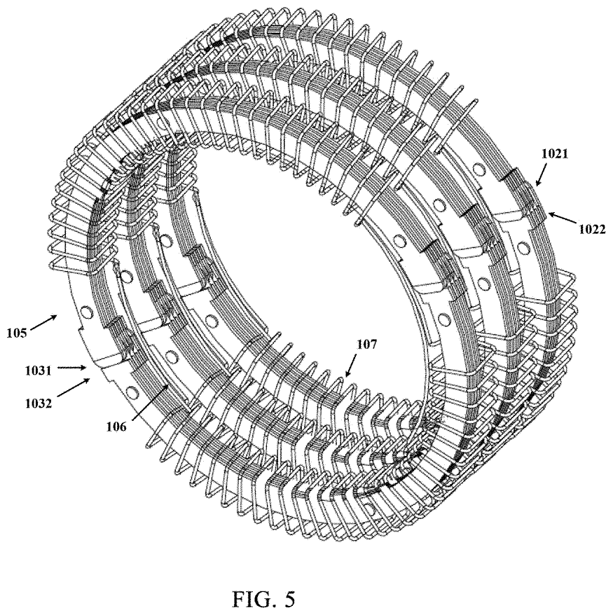

FIG. 1 to FIG. 5 illustrate a detachable multi-core current transformer 100 according to one embodiment of the present application. FIG. 1 illustrates an overall structural schematic view of the detachable multi-core current transformer. FIG. 2 and FIG. 3 illustrate a structural schematic view of a transformer assembly (for example, a first transformer assembly) in the detachable multi-core current transformer. FIG. 4 illustrates an interface schematic view of a transformer assembly (for example, first transformer assembly) in the detachable multi-core current transformer. FIG. 5 illustrates a structural schematic view after connection of three closed ring-shaped iron cores in the detachable multi-core current transformer. It should be understood that the current transformer having three iron cores illustrated in the drawings of the present application is only exemplary, and a detachable multi-core current transformer having two or four iron cores or other number of iron cores may also be used to simultaneously measure AC and DC components of current in a cable under test.

As illustrated in FIG. 1, the current transformer 100 includes a first transformer assembly 1011 and a second transformer assembly 1012. The first transformer assembly 1011 is substantially in a semi-ring shape, two ends of which are respectively a first assembly end and a second assembly end. The second transformer assembly 1012 is substantially in a semi-ring shape, two ends of which are respectively a third assembly end and a fourth assembly end. After connected, the two transformer assemblies 1011 and 1012 are substantially in a circular ring shape. In some embodiments, the first transformer assembly 1011 may also be in a semi-ring shape with an extended radian of no more than 180 degrees, such as an arc of about 120 degrees or an arc of other radians. Correspondingly, the second transformer assembly 1012 may be in a semi-ring shape with an extended radian of more than 180 degrees, such as an arc of about 240 degrees or an arc of other radians. The two transformer assemblies 1011 and 1012 may also be in other suitable shapes as long as when the two transformer assemblies are connected with each other, an enclosed area can be defined therebetween for a cable under test to pass therethrough.

The first transformer assembly 1011 includes a first housing 1041, the second transformer assembly 1012 includes a second housing 1042, and the first housing and second housing are respectively wound with coils. The first assembly end, the second assembly end, the third assembly end, and the fourth assembly end are respectively provided with a first interface 1021, a second interface 1031, a third interface 1022, and a fourth interface 1032. The first interface 1021 may be detachably connected with the third interface 1022, and the second interface 1031 may be detachably connected with the fourth interface 1032, such that the two transformer assemblies can be conveniently mounted and dismounted, and the current transformer 100 can be switched between an open state and a closed state. In some embodiments, a coil may be wound only on the first housing or only on the second housing.

In some embodiments, only the first interface 1021 and the third interface 1022 can be disconnected from each other, and the second interface 1031 and the fourth interface 1032 are always connected with each other, such that when the current transformer 100 is in an open state, the two transformer assemblies can be partially separated. In an actual measurement, when the first interface 1021 and the third interface 1022 are disconnected from each other, a gap therebetween only needs to be larger than the diameter of the cable under test such that the cable under test is allowed to pass therethrough. In some alternative embodiments, only the second interface 1031 and the fourth interface 1032 can be disconnected from each other.

As illustrated in FIG. 2 and FIG. 3, the first transformer assembly 1011 includes a first group of three iron core components 1051, 1061 and 1071, which are enclosed in the first housing 1041. In the present embodiment, the three iron core components are substantially in a semi-ring shape, have substantially the same size, and are vertically stacked on top of one another, such that two ends of all iron core components are aligned with one another, and the adjacent iron core components are electrically isolated from each other. The iron core components are made of a magnetic material such as iron, nickel or iron-nickel alloy, and the magnetic material is preferably an iron-nickel alloy material, such as permalloy. Alternatively, the outside of the first housing is further provided with a metal shielding layer (not shown), which accommodates the first housing 1041, the first group of three iron core components, and coils on each iron core component and the first housing, so as to protect the iron cores from being affected by an external electric field. In some alternative embodiments, the metal shielding layer is included in the first housing 1041.

Each iron core component 1051, 1061, or 1071 is wound with a coil (not shown), and optionally, the coil wound on each iron core component substantially extends over the entire length from the first assembly end to the second assembly end. The two ends of each iron core component are respectively provided with interdigitated structures at the first interface 1021 and the second interface 1031 for connecting with the interdigitated structures of the third interface 1022 and the fourth interface 1032 in an interdigitated manner. The interdigitated structures may have high mating accuracy. For example, the unilateral gap between digits may be as small as 0.05 mm.

The first interface 1021 and the second interface 1031 may be respectively provided with a guide member for guiding the connection between the interfaces. For example, as illustrated FIG. 4, the guide member at the first interface 1021 includes three guide elements, and each guide element surrounds one end of one iron core component of the first group of three iron core components to guide the connection between the first interface 1021 and the third interface 1022. Taking a guide element 1081 surrounding one end of an iron core component 1051 (not shown in FIG. 4) at the first interface 1021 as an example, the guide element 1081 includes a protrusion part 1111 and a recess part 1121, which are respectively located on the two sides of the interdigitated structure 1091 at one end of the iron core component 1051. When the first interface 1021 is connected with, for example, the third interface 1022 (not shown in FIG. 4), the protrusion part 1111 is mated with the recess part of the guide element of the third interface 1022, and the recess part 1121 is mated with the protrusion part of the guide element of the third interface 1022. The other two guide elements at the first interface 1021 and the three guide elements at the second interface 1031 have the same structure as the guide element 1081, which will not be repeated here.

According to the needs, one interface may include other numbers of guide elements. For example, the first interface 1021 and the second interface 1031 may respectively include only one guide element. At the same time, the guide member may also have other suitable structures, such as a shaft-hole mating structure. The guide member at the interface may be mounted on the first housing, the shielding layer or other components of the first transformer assembly.

The second transformer assembly 1012 includes components such as a second group of three iron core components (not shown in FIG. 2 or FIG. 3) enclosed in the second housing 1042. The shape, structure and the like of the second transformer assembly 1012 and the components thereof are the same as those of the first transformer assembly 1011 or are mated with those of the first transformer assembly 1011, which will not be repeated here. Each iron core component of the second group of three iron core components corresponds to one iron core component of the first group of three iron core components.

When the two interfaces of the first transformer assembly 1011 and the two interfaces of the second transformer assembly 1012 are respectively connected with each other, the interdigitated structures at the interfaces may be interdigitated with each other to form three stacked closed ring-shaped iron cores 105, 106 and 107 (see FIG. 5). The closed ring-shaped iron cores may substantially be in a circular ring shape or any other suitable closed ring shape. The first housing 1041 is connected with the second housing 1042 to form a closed ring-shaped housing to accommodate the three closed ring-shaped iron cores therein. The three guide elements at the first interface 1021 are respectively mated with the three guide elements at the second interface 1022, and the three guide elements at the second interface 1031 are respectively mated with the three guide elements at the fourth interface 1032, such that the protrusion part in each guide element is inserted into the recess part in the corresponding guide element to guide the interfaces to be aligned with each other during connection and prevent offset.

One end of the coil on each iron core component is connected with one end of the coil on the corresponding iron core component on the other transformer assembly, such that each stacked closed ring-shaped iron core is wound with a complete coil, which facilitates current sensing. Similarly, after mounting, one end of the coil wound on the first housing 1041 and one end of the coil wound on the second housing 1042 are also connected with each other at the interfaces to form a complete coil wound on the complete housing.

In some embodiments, for at least one closed ring-shaped iron core, the coil is wound only on one iron core component of the two corresponding iron core components forming the closed ring-shaped iron core, that is, the coil is wound only on one half of a certain closed ring-shaped iron core, and the coil is not wound on the other half. The current transformer of this design may also realize the measurement of the DC component and the AC components of the current.

In some embodiments, the first housing and the second housing may be omitted, and the coils wound on the first housing and the second housing may be directly wound on the outside of the first group of the three stacked iron core components and the second group of the three stacked iron core components, respectively.

In some embodiments, the current transformer may further include one or more fasteners for fixing the first transformer assembly and the second transformer assembly together when the interfaces are connected with each other. The fastener may be a bolt and a nut or any other suitable element for fastening connection, which is not limited in the present application.

In order to measure the current in the cable under test, a user may firstly disconnect the first interface from the third interface and/or the second interface from the fourth interface, such that the current transformer 100 is in an open state, and the first transformer assembly 1011 and the second transformer assembly 1012 are at least partially separated, so that the cable under test can be placed in an opening between the disconnected interfaces and thus located between the two transformer assemblies. The operator may then reconnect the disconnected interfaces such that the two transformer assemblies can be remounted to form a closed current transformer 100, and the cable under test can pass through and remains in an enclosed area defined between the two transformer assemblies. When the current flows through the cable under test, induced current related to the current under test is generated in the coil wound on the closed ring-shaped iron core. In particular, the current in the cable under test can be conveniently and accurately measured by measuring the induced current in the coil on the closed ring-shaped housing.

In the present embodiment, provided is a multi-core current transformer which can be disassembled into two separate transformer assemblies. The cable under test can enter and pass through the enclosed area in the current transformer without powering off the equipment under test, such that the DC and AC components of the current in the cable under test can be conveniently measured. The measuring equipment is especially suitable for the measurement of equipment which is not convenient to power off and start, such as solar power generation testing, medical instrument testing, electric vehicle testing, power analysis, and power quality testing.

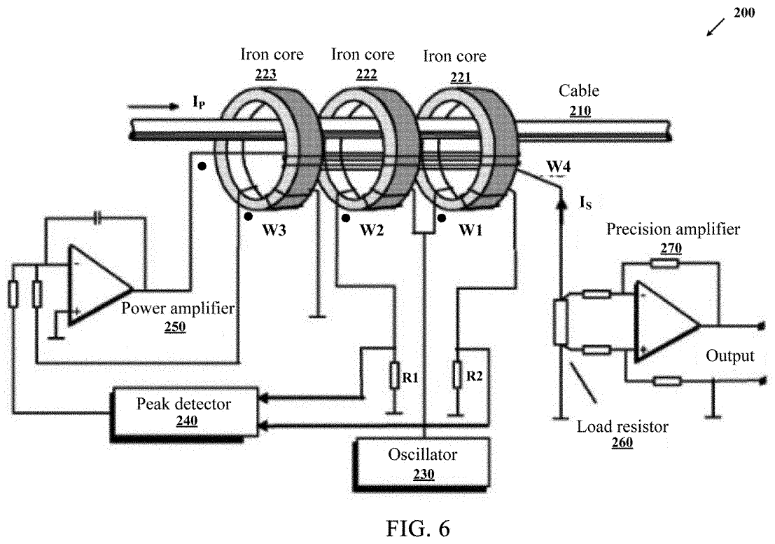

FIG. 6 illustrates a circuit 200 for measuring current by using the detachable multi-core current transformer illustrated in FIG. 1 to FIG. 5. The circuit 200 includes a detachable multi-core current transformer 220 in a connected state, which includes three closed ring-shaped iron cores 221, 222 and 223 stacked sequentially. The specific structure of the current transformer 220 has been described in detail with reference to FIG. 1 to FIG. 5 above. For the purpose of clarity, only three closed ring-shaped iron cores in the current transformer in the connected state and coils wound on each iron core are illustrated in FIG. 6, while other components in the current transformer are omitted. A coil W1 is wound on the iron core 221, a coil W2 is wound on the iron core 222, a coil W3 is wound on the iron core 223, a coil W4 is wound on a housing (not shown) enclosing the three iron cores, and the dotted terminals of the coils are marked with black dots in the figures. A cable under test 210 passes through an internal area in the three closed ring-shaped iron cores, and primary current IP flows through the cable under test 210. It should be understood that a current transformer having two iron cores or four iron cores or other number of iron cores may also be used to implement the circuit illustrated in FIG. 6.

The circuit 200 further includes an oscillator 230, which is coupled to the dotted terminal of the coil W1 and the non-dotted terminal of the coil W2 and used to drive the iron core 221 and the iron core 222. The non-dotted terminal of the coil W1 and the dotted terminal of the coil W2 are respectively coupled to a first input terminal and a second input terminal of a peak detector 240, and the first input terminal and the second input terminal of the peak detector 240 are grounded through a resistor R1 and a resistor R2 respectively. An output terminal of the peak detector 240 is coupled to a first input terminal of a power amplifier 250, the first input terminal of the power amplifier 250 is also coupled to the dotted terminal of the coil W3, and a second input terminal of the power amplifier 250 and the non-dotted terminal of the coil W3 are grounded, respectively. An output terminal of the power amplifier 250 is coupled to the dotted terminal of the coil W4.

In the circuit 200, the primary current IP flowing through the cable under test 210 generates a flux in the iron core, which is offset by secondary current IS in the coil W4. All remaining flux will be sensed by the three closed ring-shaped iron cores 221, 222 and 223 wound with coils.

The iron core 221 and the iron core 222 are used to sense the DC part of the remaining flux, and the iron core 223 is used to sense the AC part of the remaining flux. The oscillator 230 drives, in an opposite direction, the two iron cores (221, 222) for sensing the DC part of the induced current to be in a saturated state. If the remaining DC flux is 0, the peak values of the generated current in two directions are equal; if the remaining DC flux is not 0, the difference between the peak values is directly proportional to the remaining DC flux. The peak detector 240 is a dual-peak detector for measuring the DC component of the primary current IP by comparing the peak values of the currents in the two directions. The iron core 223 is used to induce the AC component of the primary current IP and to generate induced current in the coil W3. After adding the AC component induced by the iron core 223 to the output of the peak detector 240, a control loop is formed to generate the secondary current IS to make the flux zero. The power amplifier 250 supplies the secondary current IS to the coil W4. The secondary current IS is mirror current which is proportional to the primary current IP. The measurement of the current IP under test can be realized by measuring the secondary current IS.

In some embodiments, the non-dotted terminal of the coil W4 is connected to a load resistor 260 to convert a current signal in W4 into voltage. The two ends of the load resistor 260 are also coupled to two input terminals of a precision amplifier 270. The precision amplifier 270 is a very stable differential amplifier which generates output voltage with high accuracy, the output voltage is proportional to the secondary current IS, and thus it can be used to represent the primary current IP in the cable under test.

The number of turns of the coils W1, W2, W3, and W4 illustrated in FIG. 6 is only exemplary. In practice, an appropriate number of turns may be selected according to the actual needs to implement the present invention.

FIG. 6 illustrates a circuit for sensing current based on peak detection. It should be understood that the detachable multi-core current transformer disclosed in the present application may also be used in other suitable current measurement circuits, for example, a circuit based on self-excited oscillation detection, a circuit based on second harmonic detection, etc.

In practice, the current transformer in FIG. 1 to FIG. 5 may also be implemented as having other number of iron cores. In some embodiments, the detachable multi-core current transformer may be provided with two iron cores, and the structure thereof is substantially the same as that of the detachable three-core current transformer described with reference to FIG. 1 to FIG. 5, except that each of the first group of iron core components and the second group of iron core components includes two iron core components. In this way, when the first transformer assembly and the second transformer assembly are connected with each other, two closed ring-shaped iron cores can be formed. Each closed ring-shaped iron core is wound with a coil, which is equivalent to the coils W1 and W2 in FIG. 6. The outside of the two closed ring-shaped iron cores is further wound with two coils, which are equivalent to the coils W3 and W4 in FIG. 6. When the cable under test passes through the enclosed area defined between the two transformer assemblies, the current in the cable under test can be measured by measuring the induced current in the coil equivalent to W4.

In some embodiments, the detachable multi-core current transformer may be provided with four iron cores, and the structure thereof is substantially the same as that of the detachable three-core current transformer described with reference to FIG. 1 to FIG. 5, except that each of the first group of iron core components and the second group of iron core components includes four iron core components. In this way, when the first transformer assembly and the second transformer assembly are connected with each other, four closed ring-shaped iron cores can be formed. Each closed ring-shaped iron core is wound with a coil, which is equivalent to the coils W1, W2, W3, and W4 in FIG. 6. When the cable under test passes through the enclosed area defined between the two transformer assemblies, the current in the cable under test can be measured by measuring the induced current in the coil equivalent to W4.

It should be noted that although several modules or sub-modules of the current transformer and the current measurement circuit using the same have been mentioned in the above detailed description, such division is exemplary and not mandatory. Practically, according to the embodiments of the present application, the features and functions of two or more modules described above may be embodied in one module. Conversely, the feature and function of one module described above may be divided and embodied in multiple modules.

Other variations to the disclosed embodiments can be understood and effected by those of ordinary skill in the art from a study of the specification, the disclosed contents, the accompanying drawings, and the appended claims. In the claims, the word “comprise” does not exclude other elements or steps, and the word “a” or “an” does not exclude plurality. In practical application of the present application, one component may perform functions of multiple technical features referred to in the claims. Any reference signs in the claims should not be construed as limiting the scope.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled.

1. A current transformer, comprising:
a first transformer assembly, two ends of the first transformer assembly being provided with a first assembly end and a second assembly end, the first transformer assembly comprising a first group of stacked iron core components, the first group of iron core components being provided with a first interface defined at the first assembly end and a second interface defined at the second assembly end; and
a second transformer assembly, two ends of the second transformer assembly being provided with a third assembly end and a fourth assembly end, the second transformer assembly comprising a second group of stacked iron core components, the second group of iron core components being provided with a third interface defined at the third assembly end and a fourth interface defined at the fourth assembly end,
wherein:
at least one of the first interface and the second interface is detachably connected with at least one of the third interface and the fourth interface, so as to detachably connect the first transformer assembly and the second transformer assembly;
the first transformer assembly and the second transformer assembly are configured such that when connected with each other, the first group of iron core components and the second group of iron core components are combined to form a plurality of closed ring-shaped iron cores, and at least two closed ring-shaped iron cores of the plurality of closed ring-shaped iron cores are respectively wound with coils; and
an enclosed area is defined between the first transformer assembly and the second transformer assembly such that when a cable under test passes through the enclosed area, induced current related to current in the cable under test is generated in at least one coil of the coils.

2. The current transformer according to claim 1, wherein at least one coil is wound on the outside of the plurality of closed ring-shaped iron cores and is configured to generate induced current related to the current in the cable under test when the cable under test passes through the enclosed area.

3. The current transformer according to claim 2, wherein the first group of iron core components comprises two iron core components, the second group of iron core components comprises two iron core components, and when the first transformer assembly and the second transformer assembly are connected with each other, the two iron core components of the first group of iron core components and the two iron core components of the second group of iron core components are combined to form two closed ring-shaped iron cores, each closed ring-shaped iron core is respectively wound with a coil, and the outside of the two closed ring-shaped iron cores are further wound with two coils.

4. The current transformer according to claim 2, wherein the first group of iron core components comprises three iron core components, the second group of iron core components comprises three iron core components, and when the first transformer assembly and the second transformer assembly are connected with each other, the three iron core components of the first group of iron core components and the three iron core components of the second group of iron core components are combined to form three closed ring-shaped iron cores, each closed ring-shaped iron core is respectively wound with a coil, and the outside of the three closed ring-shaped iron cores is further wound with a coil.

5. The current transformer according to claim 1, wherein the first group of iron core components comprises four iron core components, the second group of iron core components comprises four iron core components, and when the first transformer assembly and the second transformer assembly are connected with each other, the four iron core components of the first group of iron core components and the four iron core components of the second group of iron core components are combined to form four closed ring-shaped iron cores, and each closed ring-shaped iron core is respectively wound with a coil.

6. The current transformer according to claim 2, wherein:
the first transformer assembly further comprises a first housing, and the first housing is configured to confine the first group of iron core components therein;
the second transformer assembly further comprises a second housing, and the second housing is configured to confine the second group of iron core components therein; and
the first housing and the second housing are configured such that when the first transformer assembly and the second transformer assembly are connected with each other, the first housing and the second housing are combined to form a closed ring-shaped housing so as to accommodate the plurality of closed ring-shaped iron cores therein, and the at least one coil wound on the outside of the plurality of closed ring-shaped iron cores is wound on the closed ring-shaped housing.

7. The current transformer according to claim 1, wherein at least one of the first interface and the second interface and at least one of the third interface and the fourth interface are provided with interdigitated structures, and the interdigitated structures are capable of being connected with each other in an interdigitated manner when the interfaces are connected with each other.

8. The current transformer according to claim 1, wherein each of the first interface, the second interface, the third interface, and the fourth interface is provided with a guide member to guide the connection of the interface.

9. The current transformer according to claim 8, wherein the guide member of each interface comprises a plurality of guide elements, each guide element surrounds one end of one iron core component of the first group of iron core components or the second group of iron core components, each guide element is provided with a paired protrusion part and recess part, and when one interface is connected with another interface, a paired protrusion part and recess part thereof are mated with a paired protrusion part and recess part of a guide element of the other interface.

10. The current transformer according to claim 1, further comprising one or more fasteners for fixing the first transformer assembly and the second transformer assembly together when the interfaces are connected with each other.

11. The current transformer according to claim 1, wherein the first interface is detachably connected with the third interface, and the second interface is detachably connected with the fourth interface.

12. The current transformer according to claim 1, wherein the first transformer assembly and the second transformer assembly are in a semicircular ring shape.

13. The current transformer according to claim 1, wherein at least two iron core components of the first group of iron core components and at least two iron core components of the second group of iron core components are wound with coils, and when the first transformer assembly and the second transformer assembly are connected with each other, the coils respectively wound on the at least two closed ring-shaped iron cores of the plurality of closed ring-shaped iron cores are formed by the coils on at least two iron core components of the first group of iron core components connected with the coils on at least two corresponding iron core components of the second group of iron core components.

14. The current transformer according to claim 2, wherein the outside of the first group of iron core components is wound with at least one coil, the outside of the second group of iron core components is wound with at least one coil, and when the first transformer assembly and the second transformer assembly are connected with each other, at least one coil wound on the outside of the plurality of closed ring-shaped iron cores is formed by the at least one coil wound on the outside of the first group of iron core components connected with the at least one corresponding coil wound on the outside of the second group of iron core components.

15. The current transformer according to claim 1, wherein the coil wound on each iron core component of the first group of iron core components extends over the entire length from the first assembly end to the second assembly end.

16. The current transformer according to claim 1, wherein the coil wound on each iron core component of the second group of ion-iron core components extends over the entire length from the third assembly end to the fourth assembly end.

17. The current transformer according to claim 1, wherein at least one iron core component of the first group of iron core components and the second group of iron core components is made of an iron-nickel alloy material.

18. The current transformer according to claim 1, wherein the outside of the iron core components and the coils of the first transformer assembly and the second transformer assembly is provided with a metal shielding layer for shielding an external electric field.

19. The current transformer according to claim 18, wherein:
the first transformer assembly further comprises a first housing that is configured to confine the first group of iron core components therein, and the first housing is accommodated in the metal shielding layer; and
the second transformer assembly further comprises a second housing that is configured to confine the second group of iron core components therein, and the second housing is accommodated in the metal shielding layer.
